(19) United States
(12) Patent Application Publication
(10) Pub. No.: US 2026/0293138 A1
(43) Pub. Date: Sep. 24, 2026

(54) MEMORY DEVICE AND METHOD OF MANUFACTURING THE SAME

(71) Applicant: SK hynix Inc., Icheon-si Gyeonggi-do (KR)

(72) Inventor: Do Young KIM, Icheon-si Gyeonggi-do (KR)

(73) Assignee: SK hynix Inc., Icheon-si Gyeonggi-do (KR)

(21) Appl. No.: 19/300,426

(22) Filed: Aug. 14, 2025

(30) Foreign Application Priority Data
Mar. 19, 2025 (KR) 10-2025-0035271

(51) Int. Cl. H10B 43/35; H01L 21/768; H10B 43/27

(52) U.S. Cl. CPC H10B 43/35; H10B 43/27; H10W 20/033; H10W 20/081

(57) ABSTRACT

A memory device includes a plurality of insulating interlayers alternately stacked with a plurality of gate lines on a first structure, and at least one cell plug extending through the insulating interlayers and the gate lines. A blocking layer of the cell plug manufactured in accordance with embodiments include a first blocking layer covering surfaces of the insulation patterns and the gate lines, and a second blocking pattern formed on the first blocking layer.

### CROSS-REFERENCES TO RELATED APPLICATION

The present application claims priority under 35 U.S.C. § 119(a) to Korean application number 10-2025-0035271, filed on Mar. 19, 2025, in the Korean Intellectual Property Office, which application is incorporated herein by reference in its entirety.

### BACKGROUND

### 1. Technical Field

The present disclosure relates to a semiconductor device, including but not limited to a three-dimensional memory device and a method of manufacturing a three-dimensional memory device.

### 2. Related Art

A memory device may be a volatile memory device, in which stored data is lost when the power supply is interrupted. A non-volatile memory device retains stored data when the power supply is interrupted.

Non-volatile memory devices include a NAND flash memory, a NOR flash memory, a resistive random access memory (ReRAM), a phase-change memory (PRAM), a magnetoresistive random access memory (MRAM), a ferroelectric random access memory (FRAM), a spin transfer torque random access memory (STT-RAM), and so forth

Among these memory devices, non-volatile memory devices formed as a three-dimensional structures include a cell plug formed through a plurality of insulation layers alternately stacked with a plurality of gate lines. Each of the gate lines includes a gate electrode and a gate barrier layer configured to surround the gate electrode.

### SUMMARY

According to an embodiments, a memory device may include a plurality of insulating interlayers alternately stacked with a plurality of gate lines on a first structure and a cell plug extending through the insulating interlayer and gate lines.

In an embodiment, the cell plug may include a plurality of insulation patterns, a first blocking layer, a second blocking pattern, a charge trap pattern, a tunnel insulation layer, a channel layer, and a core pillar. The insulation patterns may protrude from the insulating interlayers toward a center of the cell plug. The first blocking layer may be formed to cover surfaces of the insulation patterns and the gate lines. The second blocking pattern may be disposed on a segment of the first blocking layer adjacent to a gate line. The charge trap pattern may contact the second blocking pattern between the insulation patterns. The tunnel insulation layer may contact the charge trap patterns and may be disposed in a first direction perpendicular to the first structure. The channel layer may contact the tunnel insulation layer in the first direction. The core pillar may be surrounded by the channel layer may be disposed in the first direction perpendicular.

According to an embodiment, a method of manufacturing a memory device includes stacking insulating interlayers alternately with first sacrificial layers on a first structure; forming a first hole extending through the insulating interlayers and the first sacrificial layers in a first direction; forming insulation patterns on the insulating interlayers exposed through the first hole; forming a first blocking layer covering an exposed first surface of the first structure, surfaces of the insulation patterns, and surfaces of the first sacrificial layers; and forming a second blocking pattern on the first blocking layer, the second blocking pattern comprising spaced apart sections, disposed on a segment of the first blocking layer adjacent to a gate line.

### BRIEF DESCRIPTION OF THE DRAWINGS

FIG. 1 is a block diagram illustrating a memory device in accordance with an embodiment of the present disclosure;

FIG. 2 is a circuit diagram illustrating a memory block in the memory device of FIG. 1 in accordance with an embodiment of the present disclosure;

FIG. 3 to FIG. 5 are cross-sectional views illustrating various examples of the memory device of FIG. 1 in accordance with an embodiment of the present disclosure;

FIG. 6A to FIG. 6M are cross-sectional views of a memory device formed utilizing a method of manufacturing a memory device in accordance with an embodiment of the present disclosure;

FIG. 7A to FIG. 7G are cross-sectional views of a memory device formed utilizing a method of manufacturing a memory device in accordance with an embodiment of the present disclosure; and

FIG. 8A to FIG. 8G are cross-sectional views of a memory device formed utilizing a method of manufacturing a memory device in accordance with an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification. The dimensions and relative sizes of the layers and regions in the drawings may be exaggerated for clarity of description. The cross-hatching throughout the figures illustrates corresponding or similar areas between the figures rather than indicating the materials associated with the areas.

Terms such as “vertical,” “top,” “bottom,” “over,” “overlap,” “on,” “side,” “upper,” “lower,” “low,” “column,” “row,” “level,” and other terms implying relative spatial relationship or orientation are utilized only for the purpose of ease of description or reference to a drawing and are not otherwise limiting.

Terms such as “first” and “second” are used to distinguish between various elements and do not imply size, order, priority, quantity, or importance of the elements. For example, a first element may be referred to as a second element in one example, and the second element may be referred to as a first element in another example.

When one element is identified as “connected” to another element, the elements may be connected directly or through at least one intervening element between the elements. When two elements are identified as “directly connected,” one element is directly connected to the other element without an intervening element between the two elements.

When a gate barrier is formed with inadequate volume, fume degradation due to fluorine (F) included in the gate electrode may be generated. To form a gate barrier with adequate volume, sufficient space is provided between the cell plugs in which the gate lines are formed. One or more embodiments may include a memory device and a method of manufacturing a memory device with a sufficient space for gates between cell plugs. One or more embodiments include a memory device with improved memory cell characteristics and a method of manufacturing the memory device.

According to an embodiment, the blocking layer may be formed without partially oxidizing the sacrificial layers of a laminated structure. Thus, a diameter of the cell plug may not be increased. The diameter of the cell plug may be prevented from increasing to allow a sufficient space where a gate barrier of the appropriate volume may be formed, thereby improving cell properties. While preventing the diameter of the cell plug from increasing, a sufficient space may be provided for a charge trap pattern to be formed between vertically adjacent insulation patterns, thereby improving the cell characteristics.

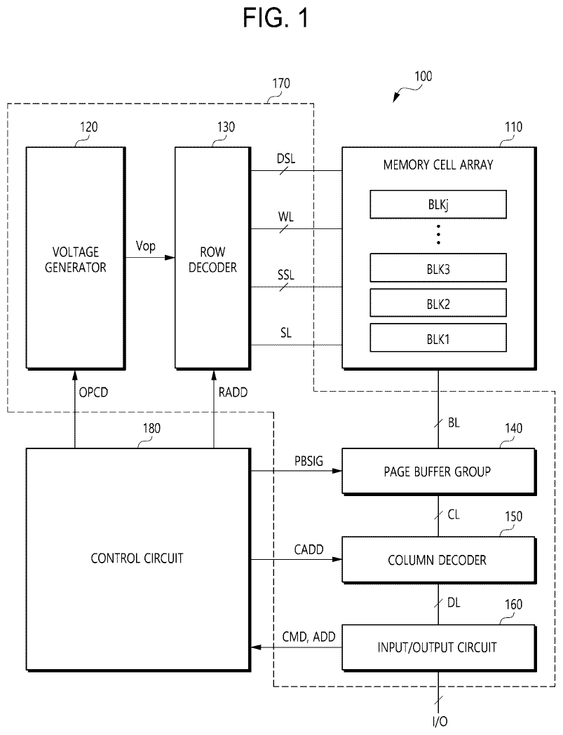

FIG. 1 is a block diagram illustrating a memory device in accordance with an embodiment of the present disclosure.

Referring to FIG. 1, a memory device 100 includes a memory cell array 110, a peripheral circuit 170 and a control circuit 180.

The memory cell array 110 includes first to jth memory blocks BLK1 to BLKj, where j is an integer greater than 1. For example, the first to jth memory blocks BLK1 to BLKj may be formed in a three-dimensional structure. Each of the first to jth memory blocks BLK1 to BLKj may include a plurality of memory cells stacked vertically over a substrate.

The memory cells may store one bit, two bits, or more bits of data depending on a program method. For example, one bit of data stored in a single memory cell are referred to as a single level cell, two bits of data stored in a single memory cell may be referred to as a multi-level cell, and three bits of data stored in a single memory cell are referred to as a triple level cell. Three bits of data stored in the single memory cell are referred to as a triple level cell. Four bits of data stored in the single memory cell are referred to as a quad level cell. 5 bits of data may be stored in a single memory cell.

The peripheral circuit 170 is configured to perform a program operation that stores data in the memory cell array 110, a read operation that outputs data stored in the memory cell array 110, and an erase operation that erases data stored in the memory cell array 110. For example, the peripheral circuit 170 includes a voltage generator 120, a row decoder 130, a page buffer group 140, a column decoder 150 and an input/output circuit 160.

The voltage generator 120 generates various operating voltages Vop used for the program operation, the read operation, and the erase operation in response to the operation code OPCD. For example, the voltage generator 120 generates a program voltage, a pass voltage, a turn-on voltage, a turn-off voltage, a ground voltage, a negative voltage, a source voltage, a verify voltage, a read voltage, an erase voltage and a pre-charge voltage in response to or based on an operation code OPCD.

The program voltage is a voltage applied to selected word lines of a plurality of word lines WL during the program operation. The program voltage is used to increase a threshold voltage of the memory cell connected to the selected word line. The pass voltage is a voltage applied to unselected word lines of the word lines WL during the program operation or the read operation. The pass voltage is used to turn on the memory cells connected to the unselected word lines.

The turn-on voltage is a voltage applied to a drain selection line DSL or a source selection line SSL. The turn-on voltage is used to turn on a drain selection transistor or a source selection transistor. The turn-off voltage is a voltage applied to the drain selection line DSL or the source selection line SSL. The turn-off voltage is used to turn off the drain selection transistor or the source selection transistor.

The ground voltage is about 0V. The negative voltage is any voltage lower than 0V. The source voltage is a voltage applied to the source line SL. The source voltage may be the negative voltage, the ground voltage, or a positive voltage. The verify voltage is a voltage to determine the threshold voltage of the selected memory cell during the program operation or the erase operation. The verifying voltages are applied to the selected word line or to all word lines connected to selected memory blocks.

The read voltage is a voltage applied to the selected word line during the read operation. The read voltage is used to determine the data stored in the memory cells. The erase voltage is a voltage applied to the source line SL during the erase operation. The erase voltage is used to lower the threshold voltage of the memory cells. The pre-charge voltage is the positive voltage applied to the source line SL to pre-charge channels of unselected strings during the verify operation or the read operation.

The row decoder 130 is connected to the voltage generator 120 via at least one global line. The row decoder is connected to the first to jth memory blocks BLK1 to BLKj via the drain selection lines DSL, the word lines WL, the source selection lines SSL, and the source lines SL. The row decoder 130 is configured to send the operating voltage Vop to the drain selection lines DSL, the word lines WL, the source selection lines SSL and the source lines SL connected to the selected memory blocks in accordance with the row address RADD.

The page buffer group 140 includes at least one page buffer (not shown) connected to the first to jth memory blocks BLK1 to BLKj in common. For example, each of the page buffers is connected to the first to jth memory blocks BLK1 to BLKj via a plurality of bit lines BL. The page buffers sense a current or a voltage on the bit lines BL in response to page buffer control signals PBSIG.

The column decoder 150 is configured to transfer data between the page buffer group 140 and the input/output circuit 160 in response to a column address CADD. For example, the column decoder 150 is connected to the page buffer group 140 via at least one column line CL. The column decoder 150 is connected to the input/output circuit 160 via at least one data line DL.

The input/output circuit 160 is configured to receive or output commands CMD, addresses ADD, or data via the input/output lines I/O. For example, the input/output circuit 160 transmits the commands CMD and the addresses ADD received from an external controller to the control circuit 180 via the input/output lines I/O. The input/output circuit 160 transmits data received from an external controller to the column decoder 150 via the input/output lines I/O. Alternatively, the input/output circuit 160 outputs data received from the column decoder 150 to the external controller via the input/output lines I/O.

The control circuit 180 outputs the operation code OPCD, the row address RADD, the page buffer control signal PBSIG and the column address CADD in response to the command CMD and the address ADD. For example, when the command CMD input to the control circuit 180 is a command corresponding to the program operation, the control circuit 180 controls the peripheral circuit 170 to perform the program operation on the selected memory block according to the address ADD. When the command CMD input to the control circuit 180 is a command corresponding to the read operation, the control circuit 180 controls the peripheral circuit 170 to perform the read operation of the selected memory block according to the address and outputs the read data. When the command CMD input to the control circuit 180 is a command corresponding to the erase operation, the control circuit 180 controls the peripheral circuit 170 to perform the erase operation on the selected memory block.

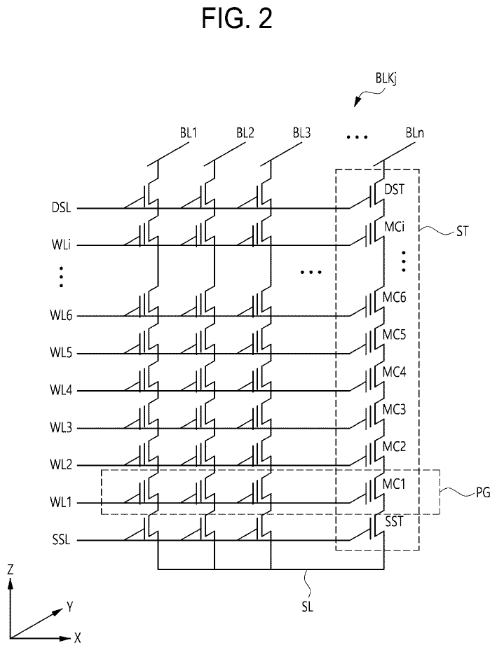

FIG. 2 is a circuit diagram illustrating memory blocks in the memory device of FIG. 1 in accordance with an embodiment of the present disclosure. Because the configurations of the memory blocks BLK1 to BLKj shown in FIG. 1 are similar, the jth memory block BLKj of the memory blocks BLK1 to BLKj is shown in FIG. 2 and described as an example.

Referring to FIG. 2, the jth memory block BLKj includes a plurality of strings ST connected between the bit lines BL1 to BLn and the source line SL. Because the bit lines BL1 to BLn extend along a Y direction and are spaced apart from each other along an X direction, the strings ST extending in a Z direction are spaced apart in the X and Y directions.

Referring to an example of one of the strings ST connected to the nth bit line BLn, the string ST includes a source selection transistor SST, a first memory cells MC1 to an ith memory cell MCi, and a drain selection transistor DST, where i is an integer greater than 1. Because the jth memory block BLKj illustrated in FIG. 2 is shown in a connection configuration of a memory block, the quantity of the source selection transistor SST, the first to ith memory cells MC1 to MCi, and the drain selection transistor DST in the string ST may vary depending on the memory device.

A gate of each source selection transistor SST in the different strings ST is connected to the source selection line SSL. Gates of the memory cells MC1 to MCi are connected to the word lines WL1 to WLi. A gate of the drain selection transistor DST is connected to the drain selection line DSL.

Among the memory cells MC1 to MCi, the memory cells formed in the same layer are connected to the same word line. For example, the first memory cell MC1 included in different strings ST is connected in common to the first word line WL1, and the second memory cell MCi included in different strings ST is connected to the second word line WLi in common. A group of memory cells in different strings ST and connected to the same word line is a page PG. The program operation and the read operation may be performed on a page PG basis, and the erase operation may be performed on a memory block basis.

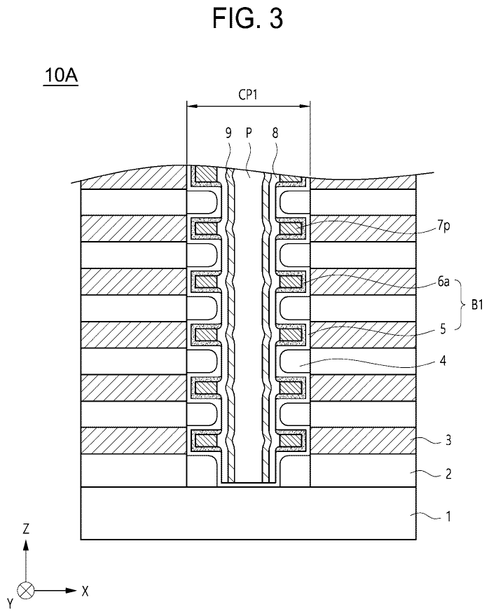

FIG. 3 is a cross-sectional view illustrating an example of the memory device of FIG. 1 in accordance with an embodiment of the present disclosure.

Referring to FIG. 3, a memory device 10A of an embodiment includes a lower structure 1, a plurality of insulating interlayers 2, a plurality of gate lines 3, and a cell plug CP1.

The plurality of insulating interlayers 2 are alternately stacked with the plurality of gate lines over the lower structure 1.

The cell plug CP1 are formed to vertically extend through the insulating interlayers 2 and the gate lines 3. The cell plug CP1 includes a plurality of insulation patterns 4, a blocking layer B1, a plurality of charge trap patterns 7p, a tunnel insulation layer 8, a channel layer 9 and a core pillar P. For example, the blocking layer B1 includes a first blocking layer 5 and a second blocking layer 6a on the first blocking layer 5.

For example, the insulating interlayers 2 have different thicknesses. Accordingly, the insulation patterns 4 formed on the insulating interlayers 2 have different thicknesses.

For example, the lower structure 1 includes a substrate or a source line. Alternately, the lower structure 1 includes a peripheral circuit structure or a stack structure including insulating interlayers 2 and a plurality of gate lines 3. The insulating interlayers 2, the insulation patterns 4, and the tunnel insulation layer 8 may include insulation materials such as an oxide material. The gate lines 3 include a conductive material. For example, the gate lines 3 include at least one of tungsten (W), cobalt (Co), nickel (Ni), molybdenum (Mo), silicon (Si), and polysilicon (poly-Si), and may include various other conductive materials.

The charge trap patterns 7p may include a nitride material but is not limited to the example of a nitride material. The channel layer 9 may include a conductive material such as a doped silicon material. The core pillar P may include an insulation material or a conductive material.

As described, the blocking layer B1 of an embodiment includes the first blocking layer 5 and the second blocking layer 6a on the first blocking layer 5. The first blocking layer 5 is formed continuously along a segment of an upper surface of the lower structure 1 and surfaces of the insulation patterns 4. The second blocking layer 6a is formed discontinuously in a direction perpendicular to the surface of the lower structure 1, such as the Z direction. The second blocking layers 6a are located on the gate lines 3 between the insulation patterns 4 in the X direction. Accordingly, the quantity of the second blocking layers 6a is the same as the quantity of the gate lines 3. Each of the second blocking patterns 6a to 6c is disposed on a segment of the first blocking layer 5 adjacent to a gate line 3. Each of the second blocking patterns 6a to 6c is disposed on a segment of the first blocking layer adjacent to a gate line. A section of the first blocking layer 5 is between a second blocking pattern 6a to 6c and a gate line 3. A second blocking pattern 6a to 6c covers a section of the first blocking layer 5 adjacent to a gate line.

The first blocking layer 5 and the second blocking layer 6a each includes an insulation material, such as the oxide material. The first blocking layer 5 is formed to cover a segment of the upper surface of the lower structure 1, the surfaces of the insulation patterns 4, and the surfaces of the gate lines 3. The second blocking layer 6a has a character “C” shape with an open end facing the tunnel insulation layer 8. For example, the second blocking layer 6a covers remaining three surfaces of the four surfaces of the charge trap pattern 7p except for the surface contacting the tunnel insulation layer 8.

In an embodiment, a thickness of the blocking layer B1 may be less than 200 Å, but is not limited to this example. A thickness of each of the first blocking layer 5 and the second blocking layer 6a may be less than 100 Å, but is not limited to this example.

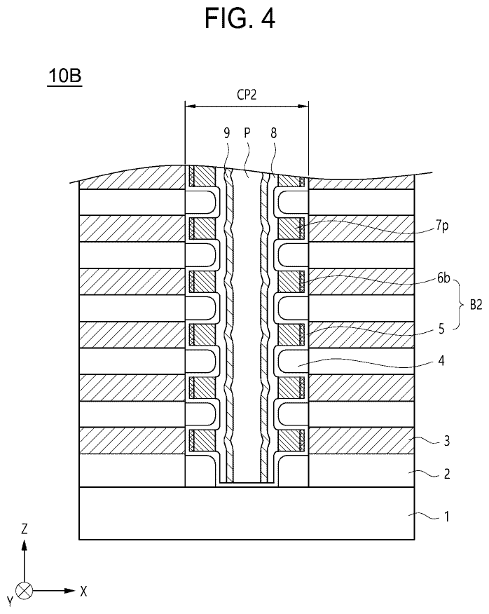

FIG. 4 is a cross-sectional view illustrating an example of the memory device of FIG. 1 in accordance with an embodiment of the present disclosure. Descriptions of similar structures of the memory device of FIG. 4 are included in the description of FIG. 3.

Referring to FIG. 4, a memory device 10B of an embodiment includes a lower structure 1, a plurality of insulating interlayers 2, a plurality of gate lines 3, and a cell plug CP2.

The plurality of insulating interlayers 2 are alternately stacked with the plurality of gate lines 3 on the lower structure 1.

The cell plug CP2 vertically extends through the insulating interlayers 2 and the gate lines 3. The cell plug CP2 includes a plurality of insulation patterns 4, a blocking layer B2, a charge trap pattern 7p, a tunnel insulation layer 8, a channel layer 9, and a core pillar P.

The blocking layer B2 of an embodiment includes a first blocking layer 5 and second blocking patterns 6b on the first blocking layer 5. The first blocking layer 5 is formed continuously along a segment of the upper surface of the lower structure 1 and the surfaces of the insulation patterns 4. The second blocking patterns 6b are formed discontinuously in a direction perpendicular to the upper surface of the lower structure 1, such as the Z direction. For example, the second blocking patterns 6b are located on the same plane in the X direction as the gate lines 3 and between the insulation patterns 4 in the Z direction. Accordingly, the quantity of the second blocking patterns 6b is the same as the quantity of the gate lines 3.

The first blocking layer 5 may include an insulation material, such as an oxide material. The second blocking patterns 6b may include an insulation material such as the oxide material. The first blocking layer 5 is formed to cover a segment of the upper surface of the lower structure 1, the surfaces of the insulation patterns 4, and side surfaces of the gate lines 3. The second blocking patterns 6b are formed between the first blocking layer 5 and the charge trap patterns 7p located on the gate lines 3. The second blocking patterns 6b may have a vertical bar or rectangular shape. Accordingly, one side of the charge trap patterns 7p of the memory device 10B of FIG. 4 contacts the tunnel insulation layer 8. The opposite side of the charge trap patterns 7p contacts the second blocking pattern 6b. An upper surface of the charge trap patterns 7p may contact the first blocking layer 5.

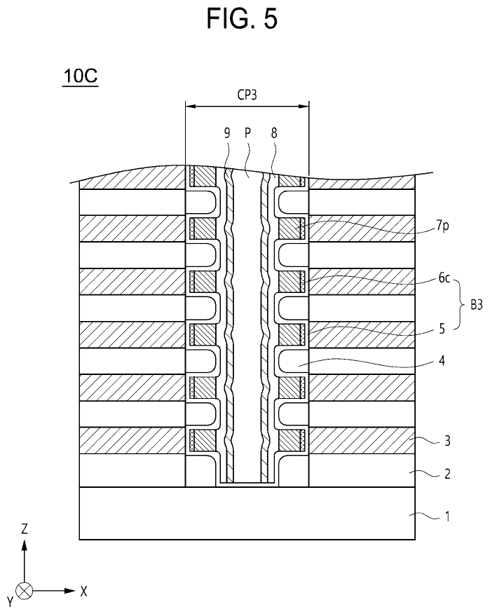

FIG. 5 is a cross-sectional view illustrating an example of the memory device of FIG. 1 in accordance with an embodiment of the present disclosure. Descriptions of similar structures of the memory device of FIG. 5 are included in the description of FIG. 3.

Referring to FIG. 5, a memory device 10C of an embodiment includes a lower structure 1, a plurality of insulating interlayers 2, a plurality of gate lines 3, and a cell plug CP3.

The plurality of insulating interlayers 2 are alternately stacked with the plurality of gate lines over the lower structure 1.

The cell plug CP1 vertically extends through the insulating interlayers 2 and the gate lines 3. The cell plug CP3 includes a plurality of insulation patterns 4, a blocking layer B3, a charge trap pattern 7p, a tunnel insulation layer 8, a channel layer 9, and a core pillar P.

The blocking layer B3 of an embodiment includes a first blocking layer 5 and second blocking patterns 6c on the first blocking layer 5. The first blocking layer 5 is formed continuously along a segment of the upper surface of the lower structure 1 and the surfaces of the insulation patterns 4. The second blocking patterns 6c are formed discontinuously in a direction perpendicular to the surface of the lower structure 1, such as the Z direction. For example, each second blocking pattern 6c is located on the same plane in the X direction as the gate lines 3 and between the insulation patterns 4 in the Z direction. Accordingly, the quantity of the second blocking patterns 6c is the same as the quantity of the gate lines 3.

The first blocking layer 5 may include an insulation material such as the oxide material. The second blocking patterns 6c may include an insulation material such as the oxide material. The first blocking layer 5 is formed to cover a segment of the upper surface of the lower structure 1, the surfaces of the insulation patterns 4 and the surfaces of the gate lines 3. The second blocking pattern 6c is formed between the first blocking layer 5 and the charge trap patterns 7p located on the levels or planes of the gate lines 3. For example, the second blocking patterns 6c may have a vertical bar or rectangular shape. Accordingly, one side of the charge trap patterns 7p of the memory device 10C of FIG. 5 contacts the tunnel insulation layer 8. The opposite side of the charge trap patterns 7p contacts the second blocking patterns 6c. An upper surface of the charge trap patterns 7p contacts the first blocking layer 5.

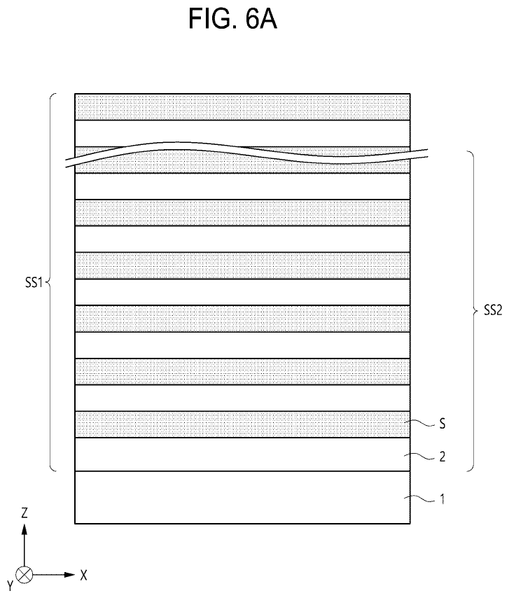

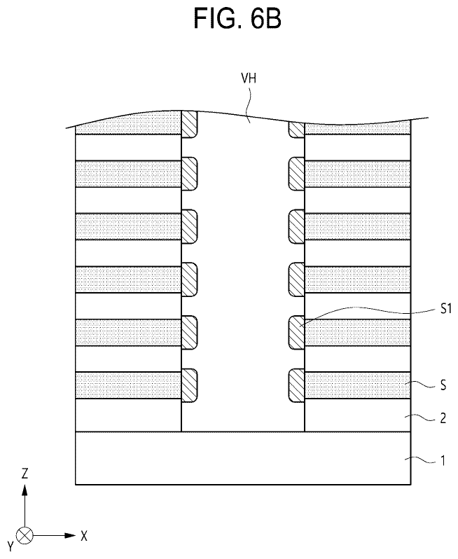

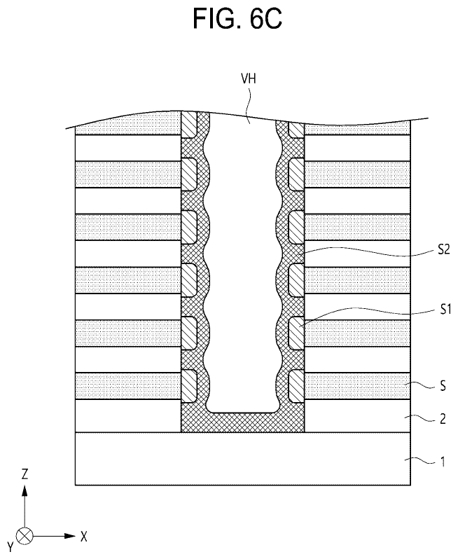

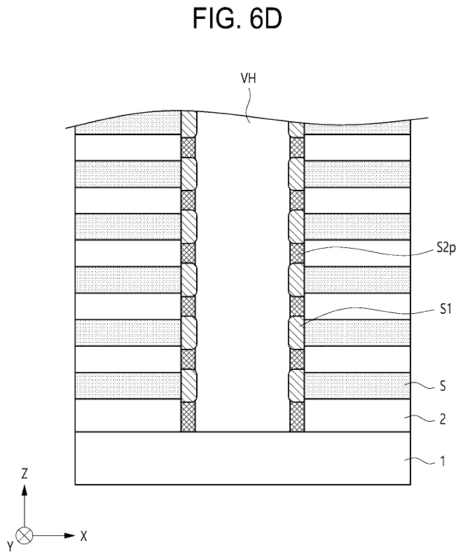

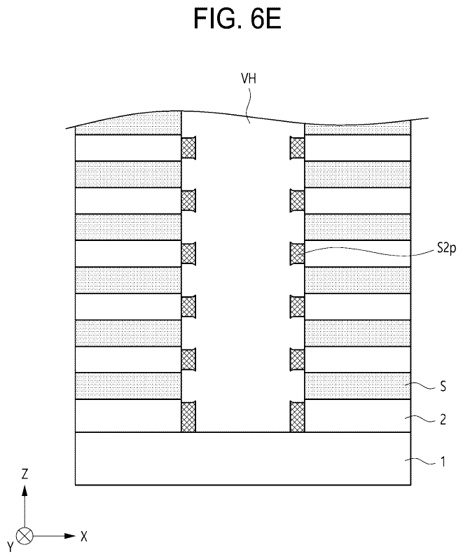

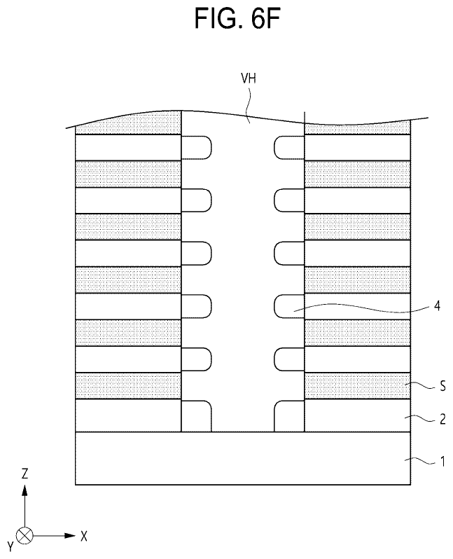

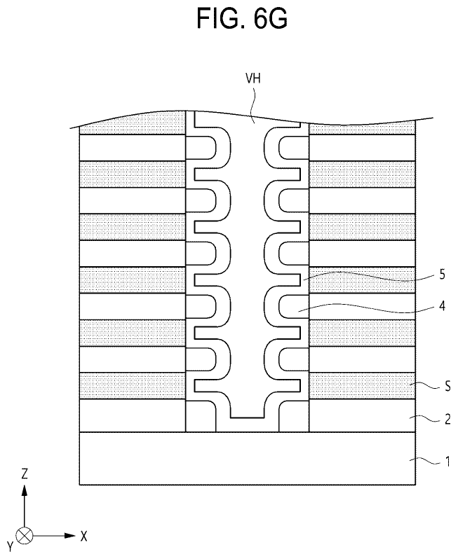

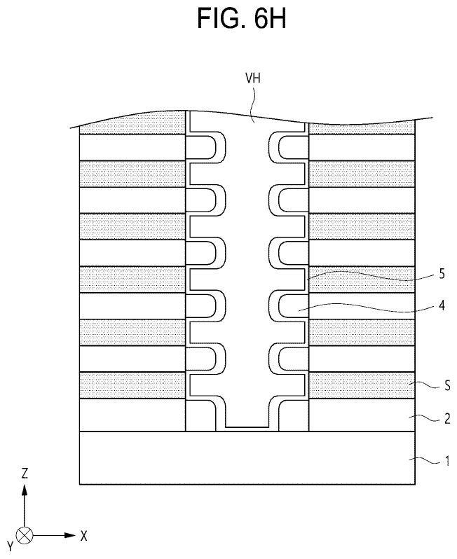

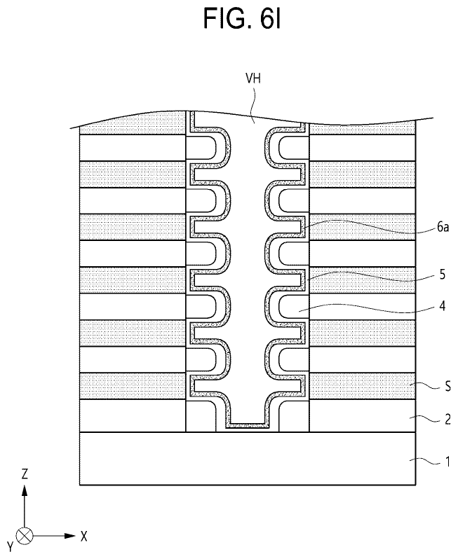

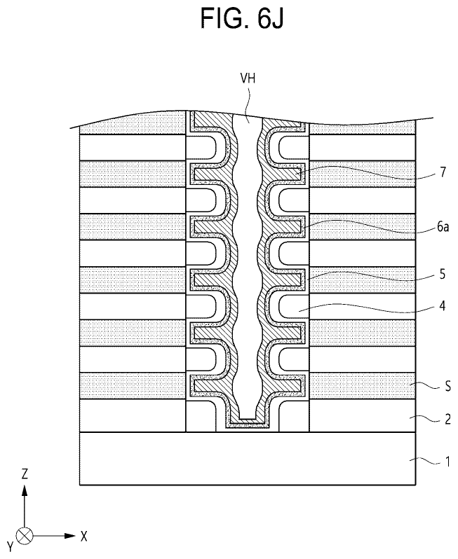

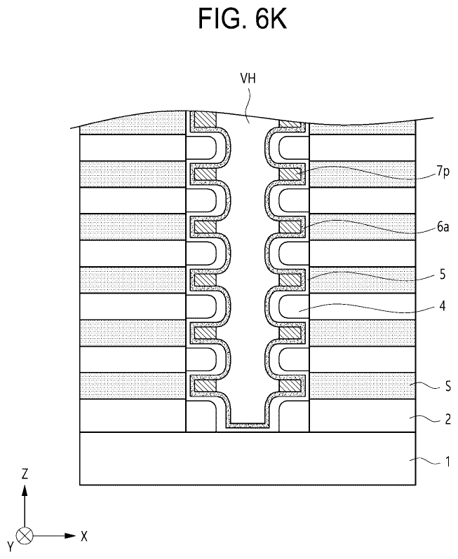

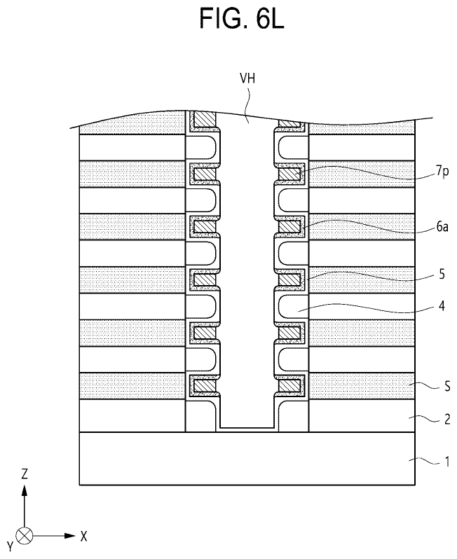

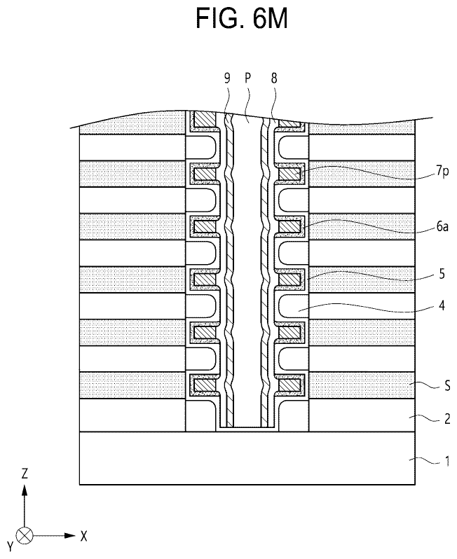

FIG. 6A to FIG. 6M are cross-sectional views of a memory device formed utilizing a method of manufacturing a memory device in accordance with an embodiment of the present disclosure.

Referring to FIG. 6A, a stack structure SS1 is formed over the lower structure 1. A plurality of insulating interlayers 2 are alternately stacked with a plurality of sacrificial layers S in a direction perpendicular to an upper surface of the lower structure 1, thereby forming the stack structure SS1. The lower structure 1 may include a substrate or source line and may include peripheral circuit structures formed on a substrate. The insulating interlayers 2 may include an insulation material such as an oxide material. The sacrificial layers S are removed in a subsequent process. The sacrificial layers S include a material having a different etch selectivity than the insulating interlayers 2. For example, the sacrificial layers S may include a nitride material.

For example, the insulating interlayers 2 may be formed to have different thicknesses. Accordingly, the insulation patterns 4 of FIG. 3 formed on the insulating interlayers 2 in a subsequent process may also have different thicknesses. The sacrificial layers S may be formed to have different thicknesses. Accordingly, the gate lines 3 of FIG. 3, which may be substituted for the sacrificial layers S in a subsequent process, may also have different thicknesses.

The stack structure SS2 shown in FIG. 6A is a section of the stack structure SS1 and is utilized to simplify description of the subsequent processes. The processes described with respect to SS2 are applicable to the stack structure SS1.

Referring to FIG. 6B, a vertical hole VH is formed vertically through the stack structure SS2 in FIG. 6A. For example, the vertical hole VH may be formed by etching sections of the insulating interlayers 2 and the sacrificial layer S until the upper surface of the lower structure 1 is exposed. Accordingly, a segment of the surface of the lower structure 1, the side surfaces of the insulating interlayers 2, and the side surfaces of the sacrificial layers S are exposed inside the vertical holes VH.

A plurality of first sacrificial layers S1 are formed on the surfaces of the sacrificial layers S exposed through the vertical holes VH. For example, the first sacrificial layers S1 may be formed via a growth method from the surfaces of the sacrificial layers S. The first sacrificial layers S1 may include an oxide material. For example, a thickness of the first sacrificial layer S1 may be thicker than a thickness of the sacrificial layer S, but is not limited to this example. For example, the thickness of the first sacrificial layer S1 may be varied such that each first sacrificial layer S1 does not contact vertically consecutive first sacrificial layers S1.

Referring to FIG. 6C, a second sacrificial layer S2 is formed to cover the first sacrificial layer S1 exposed through the vertical hole VH, the surface of the insulating interlayers 2, and the upper surface of the lower structure 1. Although the holes in FIG. 6B through FIG. 6L have different shapes and/or sizes, these holes are referred to simply as “vertical holes” for simplicity of explanation. In this example, the second sacrificial layer S2 is formed such that the second sacrificial layer S2 does not fill in the vertical hole VH, but covers inner surfaces adjacent to the vertical hole VH. The second sacrificial layer S2 may include a material including silicon.

Referring to FIG. 6D, the second sacrificial layer S2 is etched to expose the upper surface of the lower structure 1 and vertically-oriented surfaces of the first sacrificial layers S1 and form second sacrificial patterns S2p between the first sacrificial layers S1. For example, the second sacrificial layer S2 may be etched by a dry etching process and a wet etching process.

Referring to FIG. 6E, an etching process is performed to remove the first sacrificial layer S1 shown in FIG. 6D. The etching process may include a dry etching process or a dry etching process.

Referring to FIG. 6F, an oxidation process is performed to oxidize the second sacrificial patterns S2p. As described, because the second sacrificial patterns S2p include silicon or a material including silicon, the oxidation process causes each of the second sacrificial patterns S2p to become silicon oxide. Accordingly, the second sacrificial patterns S2p are processed or changed into a plurality of insulation patterns 4 corresponding to the insulating interlayers 2.

Referring to FIG. 6G, a first blocking layer 5 is formed along the upper surface of the lower structure 1 exposed through the vertical hole VH, surfaces of the insulation patterns 4, and surfaces of the sacrificial layers S. The first blocking layer 5 may include the oxide material. The insulation patterns 4 have a shape that protrudes from the insulating interlayers 2 towards a center of the vertical hole VH. The first blocking layer 5 is formed having an irregular shape along the surfaces of the insulation patterns 4 and the sacrificial layer S. The first blocking layer 5 on the insulation patterns 4 has a convex shape facing the center the vertical hole VH, and the first blocking layer 5 on the sacrificial layers S has a concave shape facing the center of the vertical hole VH. For example, the first blocking layer 5 may be formed with a thickness of less than 100 Å, but is not limited to this example.

Referring to FIG. 6H, the first blocking layer 5 may be partially etched to adjust the thickness of first blocking layer 5 to a target thickness. For example, the first blocking layer 5 may be etched by a dry etching process or a wet etching process. For example, the etching process may be performed until the thickness of the first blocking layer 5 on the sacrificial layers S becomes less than 60 Å, but is not limited to this example.

Referring to FIG. 6I, a second blocking layer 6a is formed on the first blocking layer 5. For example, the second blocking layer 6a covers an outer surface of the first blocking layer 5. Accordingly, the second blocking layer 6a includes convex sections alternating with concave sections similar to the first blocking layer 5. The second blocking layer 6a may include the oxide material. For example, the second blocking layer 6a may be formed with a thickness of less than 50 Å, but is not limited to this example.

Referring to FIG. 6J, a charge trap layer 7 is formed to cover the second blocking layer 6a exposed through the vertical hole VH. The charge trap layer 7 is formed to fill a recesses of the second blocking layer 6a. The charge trap layer 7 does not fill the inner space of the vertical hole VH. The surface of the charge trap layer 7 exposed through the vertical hole VH may have an alternating concave and convex shape. The charge trap layer 7 may include a nitride. For example, the charge trap layer 7 may be formed with a thickness of about 150 Å to about 200 Å, but is not limited to this example.

Referring to FIG. 6K, the charge trap layer 7 is partially etched to expose the second blocking layer 6a and form a plurality of charge trap patterns 7p. The charge trap layer 7 may be etched by a dry etching process or a wet etching process. For example, the etching process is performed until the charge trap layer 7 on the lower structure 1 and the charge trap layer 7 on the second blocking layer 6a are removed. Accordingly, the charge trap patterns 7p are formed between the insulation patterns 4 in the Z direction. For example, the charge trap patterns 7p may have a thickness of about 30 Å to about 80 Å, but are not limited to this example.

Referring to FIG. 6L, an oxide trim process is performed to remove sections of the first blocking layer 5 and the second blocking layer 6a. For example, the oxide trim process may be performed using hydrofluoric acid (HF). Sections of the first blocking layer 5 and the second blocking layer 6a are removed, and the remaining surfaces of the charge trap patterns 7p, for example, the top surfaces, bottom surfaces, and side surfaces, except surfaces exposed through the vertical hole VH, are covered by the second blocking layer 6a. After sections of the second blocking layer 6a are removed, second blocking patterns 6a remain. In other words, between vertically consecutive charge trap patterns 7p, the insulation patterns 4, the first blocking layer 5, and the second blocking pattern 6a including an insulation material are located, such that the charge trap patterns 7p are electrically isolated from each other.

Referring to FIG. 6M, a tunnel insulation layer 8, a channel layer 9, and a core pillar P are formed sequentially along an inner surface adjacent to the vertical hole VH in which the charge trap patterns 7p are formed. The tunnel insulation layer 8 may include an oxide material. The channel layer 9 may include a doped silicon material. The core pillars P may be formed of an insulation material or a conductive material. The tunnel insulation layer layer 8 may be formed in a cylindrical shape along the surfaces of the charge trap patterns 7p and the first blocking layer 5 and the second blocking pattern 6a. The channel layer 9 may be formed in a cylindrical shape along the inner surface of the tunnel insulation layer 8. The core pillar P may be formed in the form of a column surrounded by the channel layer 9.

Additional processes may be performed to form the structure shown in FIG. 3.

For example, an etching process may be performed to remove the sacrificial layers S from the stack structure SS2 as shown in FIG. 6A. The etching process may include a dry etching process or a wet etching process. As the sacrificial layers S are removed, a recessed region between the insulating interlayers 2 may be formed, and the surface of the insulating interlayers 2 and the first blocking layer 5 may be exposed through the recessed region.

A gate barrier layer (not shown) may be formed on the first blocking layer 5 and on the surface of the insulating interlayers 2 exposed through the recessed regions. The gate barrier layer may include titanium (Ti), titanium nitride (TiN), moly nitride (MoN), or a combination thereof. For example, the gate barrier layer may be formed to cover the surface of the insulating interlayers 2 and the surface of the first blocking layer 5.

A conductive material layer, such as a gate electrode, may be formed on the gate barrier layer within the recessed region. For example, the conductive material layer may fill the recessed region. The conductive material layer may include at least one conductive material selected from tungsten (W), cobalt (Co), nickel (Ni), molybdenum (Mo), silicon (Si), and polysilicon (poly-Si), and may include various other conductive materials.

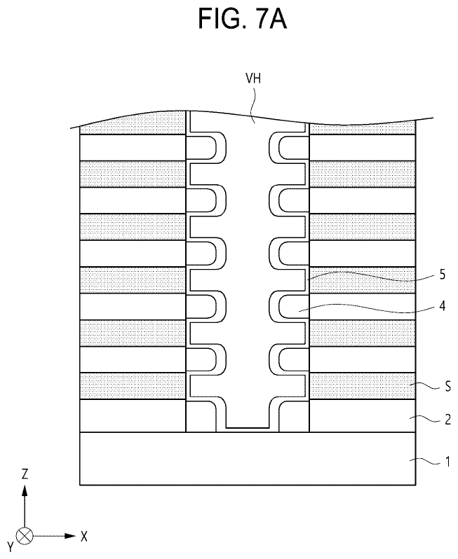

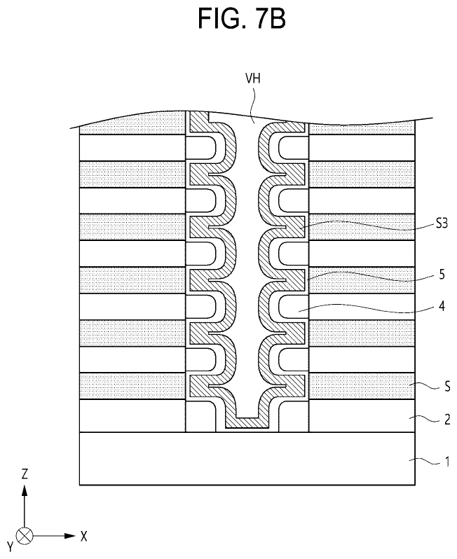

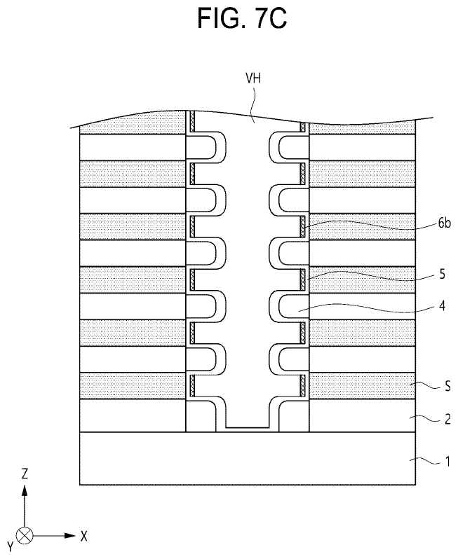

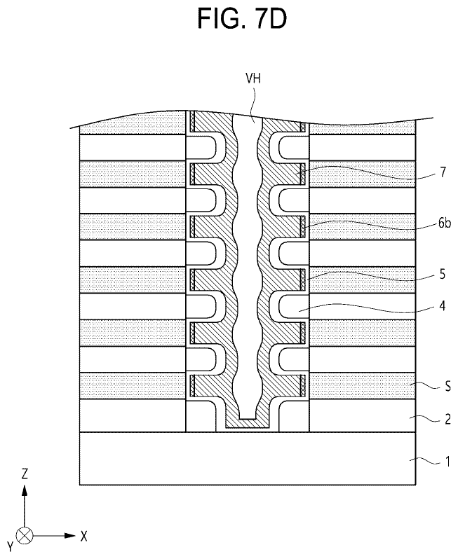

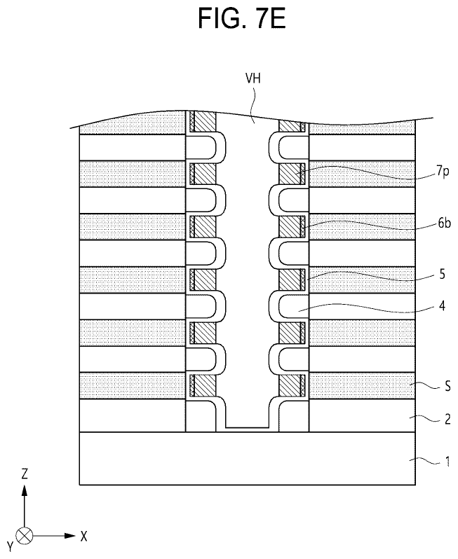

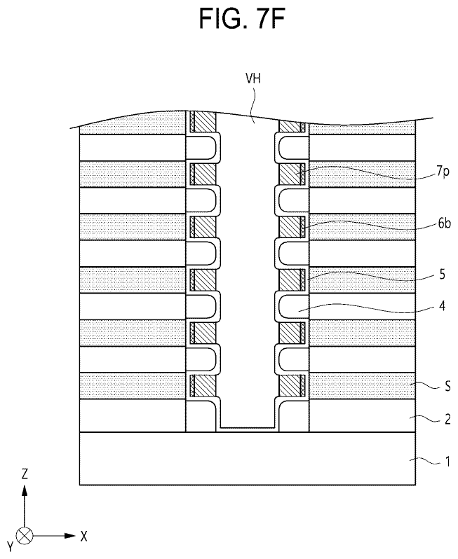

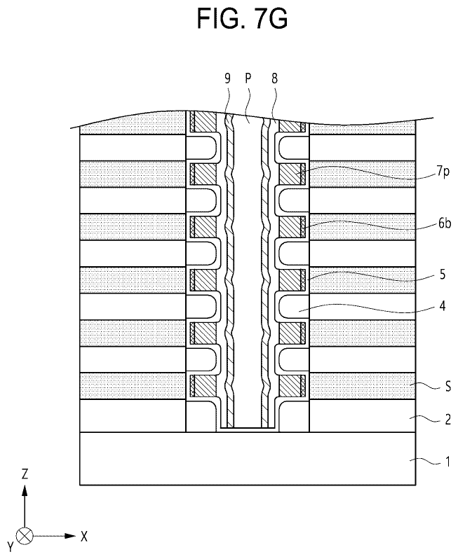

FIG. 7A to FIG. 7G are cross-sectional views of a memory device formed utilizing a method of manufacturing a memory device in accordance with an embodiment of the present disclosure. FIG. 7A to FIG. 7G are cross-sectional views of a memory device formed utilizing a method of forming a blocking layer in accordance with an embodiment different from the method of forming a blocking layer described with reference to FIG. 6G to FIG. 6I. The processes performed to form the cross-sectional view illustrated in FIG. 7A are similar to the processes described with reference to FIG. 6A to FIG. 6F.

A method of forming a blocking layer in accordance with an embodiment is described with reference to FIG. 7A to FIG. 7G, and descriptions of similar structures are included in the description of FIG. 6G to FIG. 6I.

Referring to FIG. 7A, a first blocking layer 5 including an oxide material is formed along an upper surface of the lower structure 1, the surfaces of the insulation patterns 4 and the surfaces of the sacrificial layers S exposed through the vertical hole VH. Although the holes in FIG. 7B through FIG. 7F have different shapes and/or sizes, these holes are referred to simply as “vertical holes” for simplicity of explanation. The first blocking layer 5 is formed having an irregular shape along the surfaces of the insulation patterns 4 and the sacrificial layers S. The shape of the first blocking layer 5 along the surfaces of the insulation patterns 4 has a convex shape facing the center of the vertical hole VH, and the first blocking layer 5 on the sacrificial layers S has a concave shape facing the center of the vertical hole VH. For example, the first blocking layer 5 may be formed with a thickness of less than 60 Å, but is not limited to this example.

Referring to FIG. 7B, a third sacrificial layer S3 is formed on the first blocking layer 5. For example, the third sacrificial layer S3 covers a surface of the first blocking layer 5. Accordingly, the third sacrificial layer S3 has an alternating convex and concave shape similar to the first blocking layer 5. The third sacrificial layer S3 may include a nitride material. For example, the third sacrificial layer S3 may be formed with a thickness of about 50 Å to about 150 Å, but is not limited to this example.

Referring to FIG. 7C, an etching process is performed to remove the third sacrificial layer S3. The etching process may include a dry etching process or a wet etching process. For example, the etching process is performed until the third sacrificial layer S3 remains on the first blocking layer 5 adjacent to the sacrificial layers S. Accordingly, the third sacrificial layer S3 is located on the bottom surfaces of the recessed portion of the first blocking layer 5 in the X-axis direction. The sections of the third sacrificial layer S3 are spaced apart in a vertical direction, the Z direction, and may have a vertical bar shape. For example, the third sacrificial layer S3 including the vertical bar shapes may have a thickness in the X-axis direction of about 30 Å to about 80 Å, but is not limited to this example.

An oxidation process is performed to oxidize the third sacrificial layer S3 on the bottom surfaces of the recessed portions of the first blocking layer 5 in the X-axis direction. For example, the oxidation process may be performed by an annealing process using O2 gas, but is not limited to this example. Upon completion of the oxidation process, the third sacrificial layer S3 is processed into the second blocking pattern 6b. The second blocking pattern 6b may include an oxynitride material.

Referring to FIG. 7D, a charge trap layer 7 is formed to cover the surfaces of the first blocking layer 5 and the second blocking patterns 6b exposed through the vertical hole VH. In this example, the charge trap layer 7 is formed to fill the recesses of the first blocking layer 5. The charge trap layer 7 may include a nitride material.

Referring to FIG. 7E, an etching process is performed to partially remove the charge trap layer 7. The etching process may include a dry etching process or a wet etching process. For example, the etching process is performed until the charge trap layer 7 on the first blocking layer 5 disposed on the lower structure 1 and the charge trap layer 7 on the interior sections of the first blocking layer 5 are removed. In this example, the etching process is performed until the outer surfaces of the charge trap layer 7, which may fill the recesses of the first blocking layer 5, are removed, but is not limited to this example.

Referring to FIG. 7F, an oxide trim process is performed to remove a segment of the first blocking layer 5. A segment of the charge trap layer 7 and a segment of the first blocking layer 5 are removed to form a plurality of charge trap patterns 7p vertically spaced. For example, one side of each of the charge trap patterns 7p is exposed through the vertical hole VH, an opposite side of each of the charge trap patterns 7p contacts the second blocking pattern 6b, and remaining surfaces, such as top surfaces and bottom surfaces, contact the first blocking layer 5. The sections of the charge trap patterns 7p are electrically isolated from each other because the isolation patterns 4 and the first blocking layer 5 are located between vertically consecutive charge trap patterns 7p.

Referring to FIG. 7G, a tunnel insulation layer layer 8, a channel layer 9, and a core pillar P are formed sequentially along an inner surface adjacent to the vertical hole VH in which the charge trap patterns 7p are formed.

Various processes are performed to form the structure shown in FIG. 4. For example, an etch process is performed to remove the sacrificial layers S from the stack structure SS2 in FIG. 6A. As the sacrificial layers S are removed, recesses between the insulating interlayers 2 are formed, and the recesses expose the surfaces of the insulating interlayers 2 and surfaces of the first blocking layer 5.

Gate lines 3 are formed by sequentially forming a gate barrier layer and a conductive material layer on the surfaces of the insulating interlayers 2 exposed through the recesses and on surfaces of the first blocking layer 5.

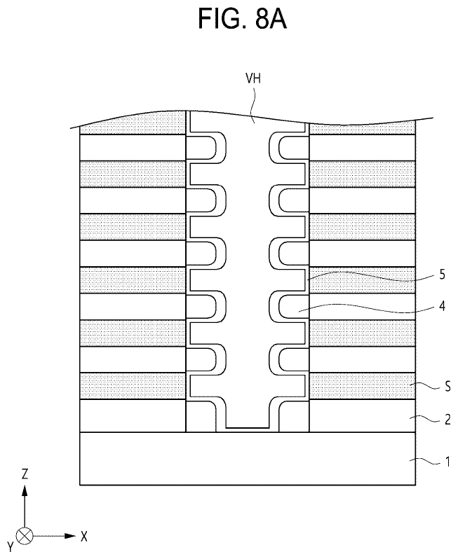

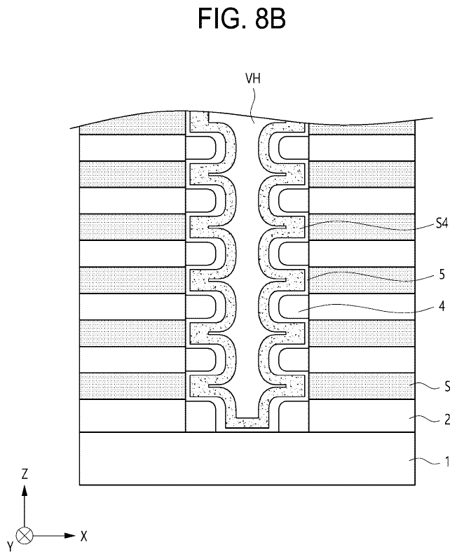

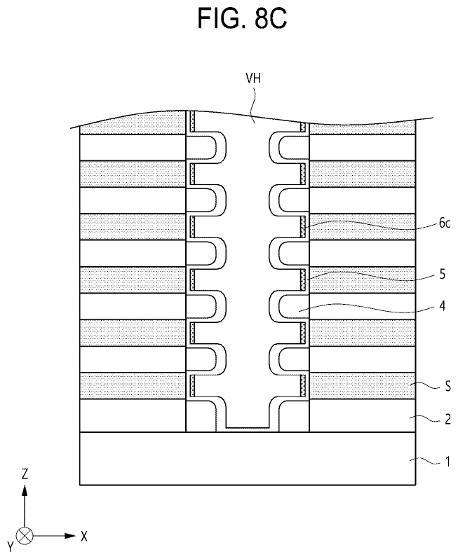

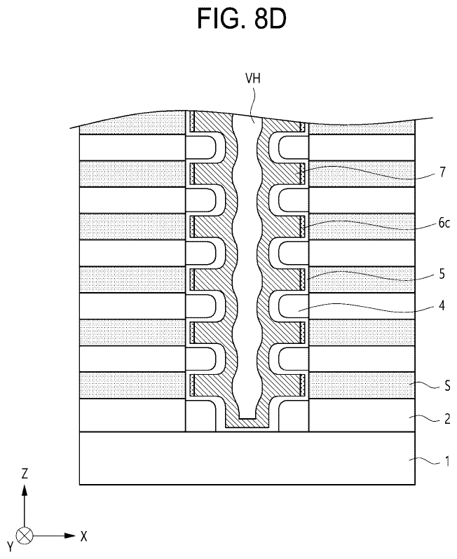

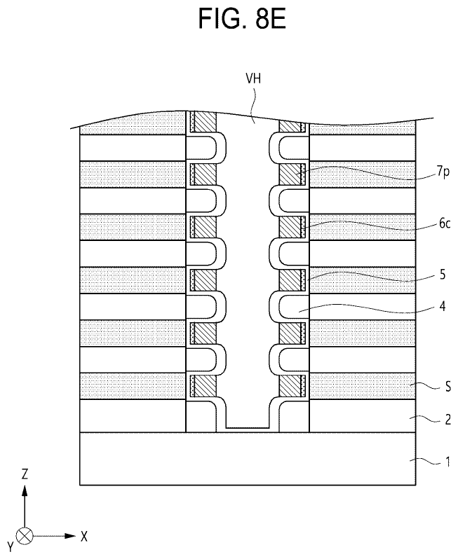

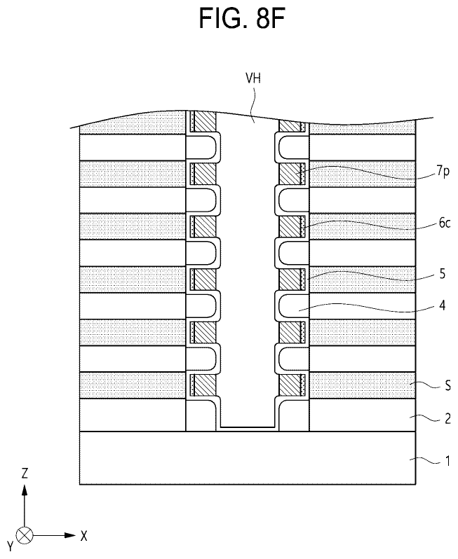

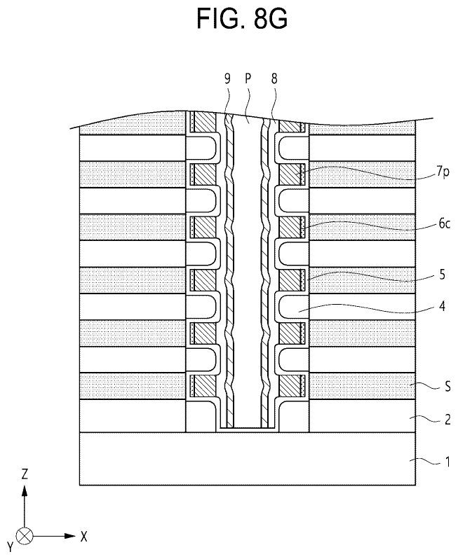

FIG. 8A to FIG. 8G are cross-sectional views of a memory device formed utilizing a method of manufacturing a memory device in accordance with an embodiment of the present disclosure. FIG. 8A to FIG. 8G are cross-sectional views of a memory device formed utilizing a method of forming a blocking layer in accordance with an embodiment different from the method of forming a blocking layer described with reference to FIG. 6G to FIG. 6I and FIG. 7A to FIG. 7G. The processes performed to form the cross-sectional view shown in FIG. 8A are similar to the processes described with reference to FIG. 6A to FIG. 6F.

A method of forming a blocking layer according to an embodiment with reference to FIG. 8A to FIG. 8G, and descriptions of similar structures are included in the descriptions of FIG. 6G to FIG. 6I and FIG. 7A to FIG. 7G.

Referring to FIG. 8A, a first blocking layer 5 including an oxide material is formed along an upper surface of the lower structure 1, surfaces of the insulation patterns 4, and surfaces of the sacrificial layers S exposed through a vertical hole VH. Although the holes in FIG. 8A through FIG. 8F have different shapes and/or sizes, these holes are referred to simply as “vertical holes” for simplicity of explanation. The first blocking layer 5 is formed having an irregular shape along the surfaces of the insulation patterns 4 and the sacrificial layers S. The first blocking layer 5 on the insulation patterns 4 has a convex shape facing the center of the vertical hole VH, and the first blocking layer 5 on the sacrificial layers S has a concave shape facing the center of the vertical hole VH. For example, the first blocking layer 5 may be formed with a thickness of less than 60 Å, but is not limited to this example.

Referring to FIG. 8B, a fourth sacrificial layer S4 is formed on the first blocking layer 5. For example, the fourth sacrificial layer S4 covers a surface of the first blocking layer 5. Accordingly, the fourth sacrificial layer S4 has an alternating convex and concave shape similar to the first blocking layer 5. The fourth sacrificial layer S4 may include a material including silicon. For example, the fourth sacrificial layer S4 may be formed with a thickness of about 50 Å to about 150 Å, but is not limited to this example.

Referring to FIG. 8C, an etching process is performed to remove the fourth sacrificial layer S4. The etching process may include a dry etching process or a wet etching process. For example, the etching process is performed such that the fourth sacrificial layer S4 remains on the first blocking layer 5 adjacent to the sacrificial layers S. Accordingly, the fourth sacrificial layer S4 is located on the bottom surfaces of the recessed portions of the first blocking layer 5 in the X-axis direction. The sections of the fourth sacrificial layer S4 are spaced apart in a vertical direction and may have a vertical bar shape.

An oxidation process is performed to oxidize the fourth sacrificial layer S4 remaining on the bottom surfaces of the recessed portions of the first blocking layer 5 in the X-axis direction. For example, the oxidation process is performed by an annealing method using O2 gas, but is not limited to this example. Upon completion of the oxidation process, the fourth sacrificial layer S4 is processed into the second blocking patterns 6c. The second blocking patterns 6c may include a silicon oxide material or oxide including silicon.

Referring to FIG. 8D, a charge trap layer 7 is formed to cover the surfaces of the first blocking layer 5 and the second blocking patterns 6c exposed through the vertical hole VH. In this example, the charge trap layer 7 is formed to fill the recesses of the first blocking layer 5. The charge trap layer 7 may include a nitride material.

Referring to FIG. 8E, an etching process is performed to partially remove the charge trap layer 7. The etching process may include a dry etching process or a wet etching process. For example, the etching process is performed until the charge trap layer 7 on the first blocking layer 5 disposed on the lower structure 1 and the charge trap layer 7 on the first blocking layer 5 are removed. In this example, the etching process is performed until the upper surface of the charge trap layer 7, which fills the recesses of the first blocking layer 5, is removed, but is not limited to this example.

Referring to FIG. 8F, an oxide trim process is performed to remove segments of the first blocking layer 5. A segment of the charge trap layer 7 and a segment of the first blocking layer 5 are removed to form a plurality of charge trap patterns 7p vertically spaced. For example, one side of each of the charge trap patterns 7p is exposed through the vertical hole VH, an opposite side of each of the charge trap patterns 7p contacts the second blocking pattern 6c, and remaining surfaces, such as the top surface and the bottom surface of the charge trap patterns 7p, contacts the first blocking layer 5. The charge trap patterns 7p may be electrically isolated from each other because the isolation patterns 4 and the first blocking layer 5 may be located between vertically consecutive charge trap patterns 7p.

Referring to FIG. 8G, a tunnel insulation layer layer 8, a channel layer 9, and a core pillar P are formed sequentially along an inner surface adjacent to the vertical hole VH in which the charge trap patterns 7p are formed.

Various processes are performed to form the structure shown in FIG. 5. For example, an etch process is performed to remove the sacrificial layers S from the stack structure SS2 in FIG. 6A. As the sacrificial layers S are removed, recesses between the insulating interlayers 2 are formed, and the recesses expose surfaces of the insulating interlayers 2 and surfaces of the first blocking layer 5.

Gate lines 3 are formed by sequentially forming a gate barrier layer and a conductive material layer on the surface of the insulating interlayers 2 exposed through the recesses and on surfaces of the first blocking layer 5.

Thus, the blocking layers B1, B2, and B3 of FIG. 3 to FIG. 5, in accordance with an embodiment may be formed without partially oxidizing the sacrificial layers S of the stack structure SS1, thus preventing an increase in the diameter of the cell plugs CP1, CP2, and CP3 of FIG. 3 to FIG. 5.

In an embodiment, by preventing the diameter of the cell plug from increasing, sufficient space may be available for charge trap pattern formation between vertically adjacent insulation patterns, which may improve cell characteristics.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A memory device comprising:
a plurality of insulating interlayers alternately stacked with a plurality of gate lines on a first structure; and
a cell plug extending through the insulating interlayers and the gate lines;
wherein the cell plug comprises:
a plurality of insulation patterns protruding from the insulating interlayers toward a center of the cell plug;
a first blocking layer covering surfaces of the insulation patterns and the gate lines;
a second blocking pattern disposed on a segment of the first blocking layer adjacent to a gate line;
a charge trap pattern contacting the second blocking pattern between the insulation patterns;
a tunnel insulation layer contacting the charge trap patterns and disposed in a first direction perpendicular to the first structure;
a channel layer contacting the tunnel insulation layer in the first direction; and
a core pillar surrounded by the channel layer and disposed in the first direction.

2. The memory device of claim 1, wherein the charge trap pattern comprises a first side contacting the tunnel insulation layer, a second side opposite the first side, and a first surface and a second surface adjacent to the insulation patterns.

3. The memory device of claim 2, wherein the second blocking pattern contacts the second side of the charge trap pattern, and the first surface and the second surface of the charge trap pattern.

4. The memory device of claim 3, wherein the second blocking pattern comprises an oxide material.

5. The memory device of claim 2, wherein the second blocking pattern contacts the second side of the charge trap pattern.

6. The memory device of claim 5, wherein the second blocking pattern comprises at least one silicon oxide material and silicon oxynitride material.

7. A method of manufacturing a memory device, the method comprising:
stacking insulating interlayers alternately with sacrificial layers on a first structure;
forming a first hole extending through the insulating interlayers and the sacrificial layers in a first direction;
forming insulation patterns on the insulating interlayers exposed through the first hole;
forming a first blocking layer covering an exposed first surface of the first structure, surfaces of the insulation patterns, and surfaces of the sacrificial layers; and
forming a second blocking pattern on the first blocking layer, the second blocking pattern comprising spaced apart sections, disposed on a segment of the first blocking layer adjacent to a gate line.

8. The method of claim 7, wherein forming the second blocking pattern comprises:
forming an oxide layer covering a surface of the first blocking layer; and
removing a segment of the oxide layer and a segment of the first blocking layer using an etching process to form the second blocking pattern contacting inner walls of recesses in the first blocking layer, wherein each of the recesses is formed at a level corresponding to one of the plurality of gate lines.

9. The method of claim 8, wherein forming the first blocking layer comprises:
forming an oxide layer covering the first surface of the first structure, the surfaces of the insulation patterns, and exposed surfaces of the sacrificial layers, the oxide layer having a first thickness; and
removing the oxide layer by an etching process to form the first blocking layer having a second thickness smaller than the first thickness.

10. The method of claim 8, further comprising:
forming a charge trap layer on an exposed surface of the oxide layer to fill the recesses of the oxide layer; and
removing a section of the charge trap layer by an etching process to form charge trap patterns within the recesses of the oxide layer.

11. The method of claim 10, further comprising:
forming a tunnel insulation layer in a direction perpendicular to the first structure and along surfaces of the insulation patterns, surfaces of the first blocking layer and the second blocking pattern, and exposed surfaces of the charge trap patterns;
forming a channel layer along a surface of the tunnel insulation layer; and
forming a core pillar surrounded by the channel layer.

12. The method of claim 11, further comprising:
removing the first sacrificial layers to form recesses; and
sequentially forming a gate barrier layer and a gate line in the recesses using at least one conductive material layer.

13. The method of claim 7, wherein forming the second blocking pattern comprises:
forming a blocking material layer covering a surface of the first blocking layer;
removing sections of the blocking material layer using an etching process to form a blocking material pattern on bottom surfaces of the first blocking layer adjacent to one of the recesses; and
oxidizing the blocking material patterns on the bottom surfaces of the first blocking layer using an oxidation process to form the second blocking pattern.

14. The method of claim 13, wherein the blocking material layer comprises at least one of a nitride material, a silicon material, and an insulation material including silicon.

15. The method of claim 13, further comprising:
forming a charge trap layer on an exposed surface of the oxide layer to fill the recesses of the oxide layer; and
removing a section of the charge trap layer by an etching process to form charge trap patterns filling the recesses of the oxide layer.

16. The method of claim 15, wherein further comprising:
forming a tunnel insulation layer in a direction perpendicular to the first structure along the surfaces of the insulation patterns, surfaces of the first blocking layer, and exposed surfaces of the charge trap patterns,
forming a channel layer along a surface of the tunnel insulation layer; and
forming a core pillar surrounded by the channel layer.

17. The method of claim 16, further comprising:
removing the sacrificial layers to form recesses; and
sequentially forming a gate barrier layer and a conductive material layer in the recesses to form gate lines.
